(19) United States
(12) Patent Application Publication
(10) Pub. No.: US 2007/0023910 A1
(43) Pub. Date: Feb. 1, 2007

(54) Dual BGA alloy structure for improved board-level reliability performance

(75) Inventor: Stanley Craig Beddingfield, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/192,876

(22) Filed: Jul. 29, 2005

(51) Int. Cl. H01L 23/48

(52) U.S. Cl. 257/738

(57) ABSTRACT

A method of improving the performance of a ball grid array package under temperature cycling and drop tests is disclosed. The method comprises forming a ball grid array with two types of solder balls. The first type of ball has a composition that improves performance under temperature cycling and the second set of solder balls has a composition that improves performance under drop testing. Preferably, the first set of balls is under the die near its perimeter and the second set of balls is located near the package perimeter, particularly at corners. A related concept pertains to a semiconductor device comprising a printed circuit board and a ball grid array package attached to the printed circuit board by an array of solder balls. The solder ball array comprises first and second sets of solder balls, the two sets having distinctly different compositions.

### FIELD OF THE INVENTION

The present invention relates generally to semi-conductor devices and more specifically to Ball Grid Array (BGA) packages.

### BACKGROUND OF THE INVENTION

Maximizing reliability, lowering cost and increasing feature density to improve performance are ongoing goals of semi-conductor device manufacturers. In particular, the demands of portable systems, such as computers and telecommunications, have spurred efforts to create reliable technology for supplying circuits having the smallest possible area and highest possible operating speed.

Semi-conductor device manufacturing typically begins with semi-conductor wafers. Various features are patterned on and into the wafers. The wafers are then singulated to form dies. To facilitate the attachment of these dies to printed circuit boards (PCBs) and to protect the dies, which are relatively fragile, the dies are typically assembled into packages before they are interconnected with PCBs. In addition to protecting the dies, the packages can provide greater surface area for connections between the dies and the PCBs than can the dies alone.

One package type that has gained popularity is the ball grid array (BGA). A BGA package connects to a PCB through an array of solder balls, which take the place of the pins of the solder pin-grid array packages. A BGA package comprises an insulating substrate in which are formed conducive traces and vias. A die can be placed on the substrate and electrically connected to the conductive traces by wire bonds. Alternatively, using the “flip-chip” approach, the die is flipped over and connected to the conducive traces through the solder bumps or other conductive material. In either case, an array of pads are provided on one side of the substrate opposite the die. The solder balls are attached to these pads.

Packaged semiconductor devices often undergo board-level reliability (BLR) testing. Two types of reliability stress tests to which PCB-mounted BGA packaged are typically subjected are temperature cycle testing and drop testing. These tests provide an indication on how the semiconductor device will perform in the field.

A common point of failure for BGA packages in BLR testing is the solder ball connections. To reduce failure rates, a number of approaches have been proposed. One approach is to alter the solder composition. For example, the background section of U.S. Pat. Pub. No. 2004/0262799 asserts that Sn—Ag solders and Sn—Cu solders have problems with respect to wettability and resistance to temperature cycling. Sn—Ag—Cu solders are said to overcome these problems and are currently be the most widely used lead-free solders. The publication proposes to improve the impact resistance of a Sn—Ag—Cu solders by adding one or more of P, Ge, Ga, Al, or Si while reducing the Cu content.

Another method of reducing BLR test failures is to employ an underfill material. Underfill materials are used to fill the spaces around the solder balls providing physical support and countering stresses during temperature cycle testing. The use of underfills, however, comes with disadvantages. Adding underfill after the BGA package is attached to the PCB adds significantly to processing time and complexity, as well as cost. Adding the material before soldering adds less complexity, but presents challenges in finding suitable underfill materials that are compatible with solders. U.S. Pat. Pub. No. 2004/0251561, for example, discloses an underfill material that hopes to address these compatibility issues.

U.S. Pat Pub. No. 2004/0262370 proposes to improve reliability by strengthening the connections between the solder balls and copper bond pads. The method comprises forming intermediate layers between the copper bond pads and the solder balls, such as a thin nickel layer or a copper-nickel-tin layer.

U.S. at. Pub. No. 2003/0170444 proposes to augment the adhesion between BGA packages and PCBs formed by solder balls with thermoplastic adhesive joints. The thermal plastic can be placed between the solder balls and adhered to the PCBs at the same time the solder balls are attached. In spite of these various efforts, there remains a long felt need for BGA packages having lower cost and higher reliability as indicated by temperature cycle and drop testing.

### SUMMARY OF THE INVENTION

One of the inventors' concepts relates to a method of improving the performance of a ball grid array package under temperature cycling and drop tests. The method comprises forming a ball grid array having two types of solder balls. The first type of ball has a composition that improves performance under temperature cycling and the second set of solder balls has a composition that improves performance under drop testing. Preferably, the first set of balls is under the die near its perimeter, where temperature cycle test failures have been found to occur most frequently. Preferably, the second set of balls is located near the perimeter of the package, particularly at corners, where the majority of drop test failure have been observed. In one embodiment, the composition and properties are varied primarily through silver content, the first set of balls preferably having little or no silver and the second set of balls having a silver content in the neighborhood of 2.5%. Preferably, both sets of balls can be reflowed at one temperature.

A related concept is a method of forming a ball grid array that comprises combining a die and a substrate into a laminate package having a larger area than the die and forming a ball grid array over the package, the array comprising a first and second set of solder balls. At least a portion of the first set of solder balls overly the die near its perimeter. At least a portion of the second set of solder balls overlies the package, but not the die, preferably in an area near the package perimeter. The first and second sets of solder balls have distinctly different compositions, although preferably both can be reflowed at one temperature.

Another related concept pertains to a semiconductor device. The semiconductor device comprises a printed circuit board and a ball grid array package attached to the printed circuit board by an array of solder balls. The solder ball array comprises a first set of solder balls and a second set of solder balls, the two sets of solder balls having distinctly different compositions.

The primary purpose of this summary has been to present certain of the inventor's concepts in a simplified form to facilitate understanding of the more detailed description that follows. This summary is not a comprehensive description of every one of the inventor's concepts or every combination of the inventor's concepts that can be considered “invention”. Other concepts of the inventor will become apparent to one of ordinary skill in the art from the following detailed description and annexed drawings. The concepts disclosed herein may be generalized, narrowed, and combined in various ways with the ultimate statement of what the inventor claims as his invention being reserved for the claims that follow.

### BRIEF DESCRIPTION OF THE DRAWINGS

FIG. 1 is schematic illustration showing defect patterns for a BGA package;

FIG. 2 is a schematic illustration of an exemplary BGA package conceived by the inventor.

### DETAILED DESCRIPTION OF THE INVENTION

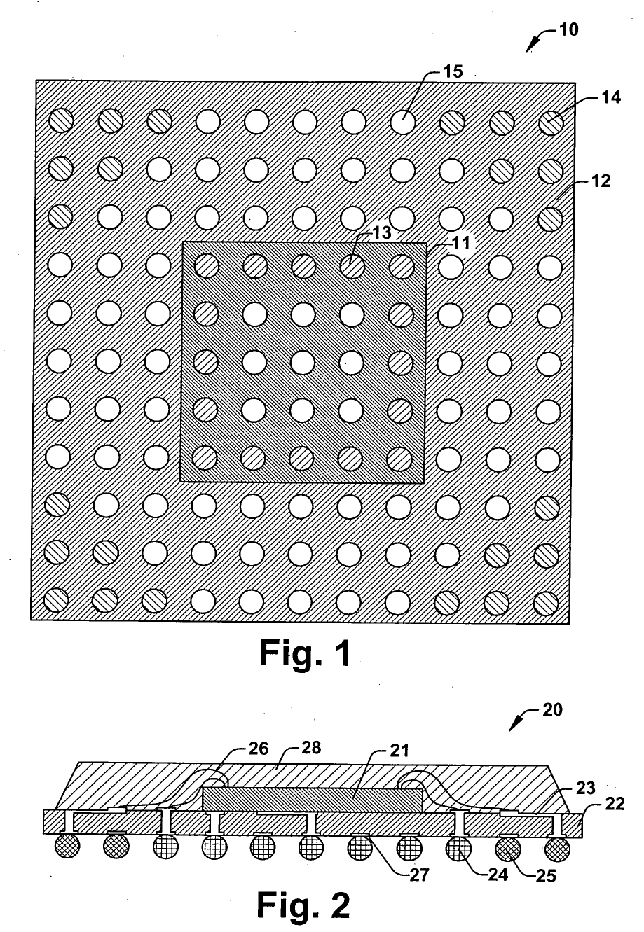

BLR temperature cycle and drop testing were carried out for PCB mounted BGA packages attached with Sn—Ag—Cu alloy solder balls. When failures occurred, the locations of the failures typically depended on the test. FIG. 1 illustrates the failure pattern for a BGA package 10 comprising a die 11 mounted on a substrate 12. When a drop test failure occurred, the failure was typically at the package corner in the area indicated by the solder balls 14. When a temperature cycle test failure occurred, it was typically at a location under the die near the die edge in the area indicated by the solder balls 13. The remaining solder balls 15 typically do not fail.

Further studies indicated that either drop test failures or temperature cycle test failures could be eliminated by varying the silver content of the solder. Starting from Sn1.2Ag0.5Cu (1.2% Ag and 0.5% Cu, balance Sn), tests were conducted with varying silver content. Drop test failures decreased with silver content, the minimum occurring at 0% silver. Temperature cycle test failures decreased with increasing silver content, a minimum occurring at about 2.5% silver.

Drawing from these results, the inventor conceived a BGA package in which a first solder ball type is to used at locations 13 and a second distinctly different solder ball type is used at locations 14. The remaining solder balls 15 can be of either type. The first solder ball type has a composition adapted to temperature cycle test performance. The second solder ball type has a composition adapted to drop test performance.

The two types of solder balls can have different reflow temperatures. In such a case, the solder balls with the higher reflow temperature are preferably placed and reflowed first and the solder balls with the lower reflow temperature can be placed and reflowed second. When the BGA package is attached to the board, a solder screened onto the board can be used to attach the package.

Preferably, however, in order to simplify the process, the solder ball compositions are chosen so that all reflow at one temperature. For example, the first set of solder balls can be Sn3.0Ag0.5Cu, which has recommended reflow temperatures in the range from about 235 to about 248° C. and the second set of solder balls can be Sn0.7Cu, which has recommended reflow temperatures in the range from about 245 to about 255° C.

The solder balls can be placed separately, but in a preferred embodiment all the solder balls in an array, including solder balls of both types, are picked and placed on the substrate at the same time. Because all the solder balls can be placed at the same time, and all can be reflowed for attachment to the substrate in one step, the inventor's concepts can be implemented with little increase in complexity. It is even reasonable to use more than two solder ball types, with the compositions varying in a spatially dependent manner to improve overall reliability.

A typical temperature cycle test comprises a temperature increase from room temperature (i.e., about 25° C.) to 125° C., a temperature decrease to 40° C., a soak at that temperature, a temperature increase back up to 125° C., a soak at that temperature, and a temperature decrease to room temperature again. A drop test, as the name implies, typically involves dropping a PCB from a predetermined height onto a hard surface.

Temperature cycle test failures are typically due to stresses resulting from mismatched thermal expansion coefficients. Mismatched thermal expansions cause solder balls to undergo prolonged stress and deformation. When the deformations are irreversible, the solder balls tend to fail. Increasing elasticity can reduce this type of failure.

Drop test failures are typically due to large, though brief, stresses. Large stresses typically cause failure by exceeding the materials ultimate tensile strength. Increasing strength can reduce this type of failure. The invention can be applied using any suitable solder ball type. Beginning from any composition, the composition can be carried systematically, BGA packages prepared, and failure rates determined. Solders failing both temperature cycling and drop tests can be eliminated. Of the remaining solders, two can be selected, one with excellent drop test performance and one with excellent temperature cycle test performance. Preferably, pairs with overlapping reflow temperature ranges are selected. Preferably, pairs with similar overall compositions are selected, whereby there is a reasonable expectation that the solder balls optimized for drop test performance with have some resilience under temperature cycle testing and vice versa.

Suitable solder ball composition pairs may exist among any of the typically used solder ball types. Typically used solder ball types include Sn—Pb solder and lead-free solders such as alloys of Sn with one or more of Ag, Cu, Sb, In, Zn, Ni, Cr, Co, Fe, O, Ge, and Ga. Specific examples of lead-free solders include Sn—Cu, Sn—Sb, Sn—Bi, Sn—Zn, and Sn—Ag alloys. Sn—Ag—Cu alloys are preferred and also preferably include 0.01 to 0.5% Ni. Eutectic solders containing lead are generally more durable, thus there is greater need for inventor's concepts within the regime of lead-free solders.

FIG. 2 is a schematic illustration of an exemplary BGA package 20 as conceived by the inventor. The BGA package 20 includes die 21 insulating substrate 22 with conductive traces and vias 23 formed therethrough, and a ball grid array comprising first solder balls 24 second solder balls 25. Bond wires 26 connect terminals on the die 21 to the conductive traces and vias 23. The wires 26 are encapsulated in solid mold compound 28, which is typically an epoxy. The solder balls 24 and 25 are attached to bond pads 27 accessible through opening in the insulating substrate 22. The solder balls 24 have a composition that favors performance under temperature cycle testing and the solder balls 25 have a different composition that favors performance under drop testing.

The die 21 includes a semiconductor. Examples of semiconductors include, without limitation, Si, GaAs, and InP. In addition to a semiconductor, the die 21 may include various elements therein and/or layers thereon. These can include metal layers, barrier layers, dielectric layers, device structures, active elements and passive elements including gates, word lines, source regions, drain regions, bit lines, bases emitters, collectors, conductive lines, conductive vias, etc. The die 21 may be bonded the insulating substrate 22 by an epoxy.

The insulating substrate 21 can be formed of any suitable material. Examples of substrate materials include ceramic, silicon, polyimide, and other organic compounds. Typical substrate materials include bismaleimide triazine and glass-fiber-reinforced epoxy (FR4). Conductive traces and vias 23 are formed in the insulating substrate 21 and provide connection pathways between terminals on the die 21 and bond pads 27. The conductive traces and vias 23 and the bond pads 27 are typically copper, although other conductive materials can also be used. A thin Ni or Ni—Au coating is preferably provided to prevent oxidation of the bond pads 27. Other coatings such as OSP are also utilized.

The example 20 uses bond wires 26 to form electrical connection with the die 21. Alternatively, the die 21 can be provided with solder bumps, flipped over, and directly attached to the conductive traces and vias 23. Solder bumps in this type of array generally have a smaller pitch than the solder balls 24 and 25. The solder bumps can be formed from a solder having a higher reflow temperature than either of the solders used for solder balls 24 and 25. Other bump materials can be utilized, such as gold, copper, etc.

The solder balls 24 and 25 preferably have a pitch less than about 1 mm, more preferably about 0.5 mm or less, most preferably about 0.4 mm or less. Reliability becomes more challenging at smaller pitches and accordingly the demand for the invention is greater. At 0.4 and 0.5 mm pitches the preferred size of the openings in the insulating substrate 22 for the bond pads 27 is about 250 μm.

Typically, the insulating substrate 22 has a greater area than the die 21. One common reason for providing a larger area is that a greater area is needed or desired for the ball grid array of balls 24 and 25 than can be provided by the die 21. A greater area may also be needed to accommodate bond pads for wire bonds. In any case, the difference in area between the die and the substrate creates areas having different behavior in BLR testing. Accordingly, one embodiment of the inventor's concepts relates to the case where the substrate 22 has a greater area than the die 21.

The inventor's concepts, however, are not so limited. They can be generalized to any ball grid array where one group of ball locations is more prone to failure under one BLR test and another group of ball locations is more prone to failure under a different BLR test. Different types of balls can be assigned to the different locations.

The BGA package 21 will typically be applied to a PCB. During the application, a flux is used to remove surface oxides and otherwise facilitate attachment. An underfill material may also be used. In a preferred embodiment, however, the need for an underfill is eliminated and an underfill is not used.

The invention as delineated by the following claims has been shown and/or described in terms of certain concepts, components, and features. While a particular component or feature may have been disclosed herein with respect to only one of several concepts or examples or in both broad and narrow terms, the components or features in their broad or narrow conceptions may be combined with one or more other components or features in their broad or narrow conceptions wherein such a combination would be recognized as logical by one of ordinary skill in the art. Also, this one specification may describe more than one invention and the following claims do not necessarily encompass every concept, aspect, embodiment, or example described herein.

The claims are:

1. A method of manufacturing a ball grid array package, comprising:
combining a die having a first area with a substrate to form a package having a second, larger area, whereby one side of the package has an area overlying the die, and a surrounding area overlying the substrate but not the die; and
forming a ball grid array of solder balls over the one side, wherein a first set of the solder balls overlies the die near its perimeter and a second set of solder balls proximate the perimeter of the package does not overly the die;
wherein the first set of solder balls has a first composition and the second set of solder balls has a second, distinctly different, composition.

2. The method of claim 1, wherein the solder balls are lead free.

3. The method of claim 1, wherein the first set of solder balls has a lower silver content than the second set of solder balls.

4. The method of claim 1, wherein the first set of solder balls has no more than about 0.3% silver and the second set of solder balls has at least about 2.0% silver.

5. The method of claim 1, wherein the substrate is organic.

6. The method of claim 1, further comprising wire bonding the die to conductive traces or vias in the substrate.

7. The method of claim 1, wherein the first and second sets of solder balls are reflowed in one reflow procedure.

8. The method of claim 1, wherein the ball grid array has a pitch of about 0.5 mm or less.

9. The method of claim 1, wherein:
the first set of solder balls is more elastic than the second set of solder balls; and
the second set of solder balls has greater ultimate tensile strength than the first set of solder balls.

10. The method of claim 1, wherein:
a ball grid array of solder balls having the first composition performs better under temperature cycle testing as compared to a ball grid array of solder balls having the second composition; and
a ball grid array of solder balls having the second composition performs better under drop testing as compared to a ball grid array of solder balls having the first composition

11. A semiconductor device, comprising:
a printed circuit board;
a ball grid array package attached to the printed circuit board by an array of solder balls;
wherein the array comprises a first set of solder balls and a second set of solder balls, the two sets of solder balls having distinctly different compositions.

12. The semiconductor device of claim 11, wherein the first set of solder balls underlies a die contained by the package, and the second set of solder balls underlies a substrate of the package, but not the die.

13. The semiconductor device of claim 11, wherein the ball grid array package is attached to the printed circuit board without underfill.

14. The semiconductor device of claim 11, wherein the solder balls are lead free.

15. The semiconductor device of claim 11, wherein the first set of solder balls has a lower silver content than the second set of solder balls.

16. The semiconductor device of claim 11, wherein the array has a pitch of about 0.5 mm or less.

17. The semiconductor device of claim 11, wherein:
the first set of solder balls is more elastic than the second set of solder balls; and
the second set of solder balls has greater ultimate tensile strength than the first set of solder balls.

18. The semiconductor device of claim 11, wherein the first and second sets of solder balls reflow at one temperature.

19. The semiconductor device of claim 11, wherein:
a ball grid array of solder balls having the composition of the first set of balls performs better under temperature cycle testing as compared to a ball grid array of solder balls having the composition of the second set of balls; and
a ball grid array of solder balls having the composition of the second set of balls performs better under drop testing as compared to a ball grid array of solder balls having the composition of the first set of balls

20. A method of improving the performance of a ball grid array package under temperature cycling and drop tests, comprising:
forming a first portion of a connection array for the ball grid array package using a first solder ball type; and
forming a second portion of the connection array using a second solder ball type;
wherein the first set of solder balls improves performance under drop testing and the second set of solder balls improves performance under temperature cycle testing, and the locations for the first and second solder ball types are selected to improve the overall ability of the ball grid array package to pass both temperature cycle and drop testing.
